(19) United States
(12) Patent Application Publication
(10) Pub. No.: US 2011/0168246 A1
(43) Pub. Date: Jul. 14, 2011

(54) THIN-FILM SOLAR CELL AND MANUFACTURING METHOD THEREOF

(75) Inventor: Chin-Yao Tsai, Tainan (TW)

(73) Assignee: AURIA SOLAR CO., LTD., Tainan (TW)

(21) Appl. No.: 13/051,918

(22) Filed: Mar. 18, 2011

(30) Foreign Application Priority Data
Mar. 22, 2010 (TW) 099108361

(51) Int. Cl. H01L 31/06; H01L 31/18

(52) U.S. Cl. 136/255; 438/69; 257/E31.126

(57) ABSTRACT

A thin-film solar cell, comprising a light transmissive substrate, a transparent electrode, a first photovoltaic layer, a second photovoltaic layer and a back electrode, is provided. The light transmissive substrate has a light incident surface and a back surface opposite to the light incident surface, and the transparent electrode is disposed on the back surface. The first photovoltaic layer is disposed on the transparent electrode, and the material of the first photovoltaic layer is an amorphous semiconductor, and the first photovoltaic layer has a first energy gap. The second photovoltaic layer is disposed on the first photovoltaic layer and has a second energy gap lower than the first energy gap. The material of the second photovoltaic layer is a micro-crystalline semiconductor, and the crystallization ratio of the second photovoltaic layer is between 30%˜100%. The second photovoltaic layer can absorb a light ray with a wavelength between 600 nm-1100 nm.

### CROSS-REFERENCES TO RELATED APPLICATIONS

This non-provisional application claims priority under 35 U.S.C. §119(a) on Patent Application No. 099108361 filed on Mar. 22, 2010, the entire contents of which are hereby incorporated by reference.

### FIELD OF THE INVENTION

The present invention relates to a solar cell and a manufacturing method thereof, and more particularly, to a thin-film solar cell with improved photo-electric conversion efficiency and a manufacturing method thereof.

### BACKGROUND OF THE INVENTION

Currently, a critical problem related to solar cells is how to improve the photo-electric conversion efficiency thereof, and any improvement in the photo-electric conversion efficiency of solar cells will lead to improvement in competitive edge of the solar cell products. The photo-electric conversion efficiency of the solar cells is affected by a number of factors, a dominant one of which is that light rays entering the solar cells cannot be fully utilized.

Generally speaking, the light spectrum of sunlight may be generally divided into the following three bands: ultraviolet (UV) light, which accounts for about 9%; visible light, which accounts for about 47%; and infrared (IR) light, which accounts for the remaining 44%. However, conventional solar cells are unable to fully absorb and convert the energy of sunlight. Specifically, most of the conventional solar cells are only able to absorb the UV light, the visible light and a small portion of the IR light of the sunlight spectrum, with most of the IR light passing through the solar cells as a loss. In other words, the conventional silicon crystal solar cells can only utilize short-wavelength portions of the sunlight spectrum but cannot utilize the long-wavelength portions of the sunlight spectrum efficiently for photo-electric conversion. Accordingly, there is still great room for improvement of the conventional solar cells.

### SUMMARY OF THE INVENTION

In view of this, the present invention provides a thin-film solar cell, which can increase the utilization factor of light rays to improve the photo-electric conversion efficiency of the thin-film solar cell.

The present invention provides a method for manufacturing a thin-film solar cell, by which the aforesaid thin-film solar cell can be manufactured.

The thin-film solar cell of the present invention comprises a light transmissive substrate, a transparent electrode, a first photovoltaic layer, a second photovoltaic layer and a back electrode. The light transmissive substrate has a light incident surface and a back surface opposite to the light incident surface. The transparent electrode is disposed on the back surface. The first photovoltaic layer, which is disposed on the transparent electrode, is made of an amorphous semiconductor material and has a first energy gap. The second photovoltaic layer is disposed on the first photovoltaic layer and has a second energy gap lower than the first energy gap. The second photovoltaic layer is made of an amorphous semiconductor material with a crystallization ratio of between 30% and 100%. The second photovoltaic layer is adapted to absorb a light ray with a wavelength of between 600 nm and 1100 nm. The back electrode is disposed on the second photovoltaic layer.

In an embodiment of the present invention, the second photovoltaic layer has an average grain size of between 50 nm and 500 nm.

In an embodiment of the present invention, the second energy gap ranges between 1.1 electron volt and 1.7 electron volt.

In an embodiment of the present invention, the thin-film solar cell further comprises a third photovoltaic layer disposed between the first photovoltaic layer and the second photovoltaic layer, wherein the third photovoltaic layer has a third energy gap higher than the second energy gap but lower than the first energy gap.

In an embodiment of the present invention, the third photovoltaic layer is made of at least one of an amorphous semiconductor material and a microcrystalline semiconductor material.

In an embodiment of the present invention, the back electrode is made of a transparent conductive material or a reflective conductive material.

In an embodiment of the present invention, when the back electrode is made of the transparent conductive material, the thin-film solar cell further comprises a light reflective layer disposed on the back electrode.

In an embodiment of the present invention, a light ray entering the thin-film solar cell via the light incident surface passes sequentially through the light transmissive substrate, the transparent electrode, the first photovoltaic layer, the second photovoltaic layer and the back electrode to the light reflective layer, and the light reflective layer at least reflects the light ray with a wavelength of substantially between 600 nm and 1100 nm.

In an embodiment of the present invention, the light reflective layer is made of one or more materials selected from a group consisting of a white paint, a metal, a metal oxide, an organic material and combinations thereof.

In an embodiment of the present invention, the second photovoltaic layer is made of germanium (Ge).

The method for manufacturing a thin-film solar cell of the present invention comprises the following steps of: providing a light transmissive substrate having a light incident surface and a back surface opposite to the light incident surface; forming a transparent electrode on the back surface; forming a first photovoltaic layer on the transparent electrode, wherein the first photovoltaic layer is made of an amorphous semiconductor material and has a first energy gap; forming a second photovoltaic layer on the first photovoltaic layer, wherein the second photovoltaic layer has a second energy gap lower than the first energy gap, and the second photovoltaic layer is made of a microcrystalline semiconductor material with a crystallization ratio of between 30% and 100%; and forming a back electrode on the second photovoltaic layer.

In an embodiment of the present invention, the method for manufacturing a thin-film solar cell further comprises performing an annealing process on the second photovoltaic layer so that the second photovoltaic layer has a crystallization ratio of between 30% and 100%.

In an embodiment of the present invention, the method for manufacturing a thin-film solar cell further comprises performing an annealing process on the second photovoltaic layer so that the second photovoltaic layer has an average grain size of between 50 nm and 500 nm.

In an embodiment of the present invention, the method for manufacturing a thin-film solar cell further comprises performing a doping process on the second photovoltaic layer so that the second energy gap ranges between 1.1 electron volt and 1.7 electron volt.

In an embodiment of the present invention, after the step of forming the first photovoltaic layer but before the step of forming the second photovoltaic layer, the method further comprises: forming a third photovoltaic layer having a third energy gap on the first photovoltaic layer, wherein the third energy gap is between the first energy gap and the second energy gap.

In an embodiment of the present invention, the method for manufacturing a thin-film solar cell further comprises performing an annealing process on the third photovoltaic layer to crystallize the third photovoltaic layer.

In an embodiment of the present invention, when the back electrode is made of the transparent conductive material, the method further comprises: forming a light reflective layer on the back electrode, wherein the light reflective layer at least reflects a light ray having a wavelength of substantially between 600 nm and 1100 nm.

In an embodiment of the present invention, when the light reflective layer is made of a conductor material, the method further comprises: forming a light transmissive insulation layer between the reflective layer and the back electrode.

In an embodiment of the present invention, the method for manufacturing a thin-film solar cell further comprises doping Ge atoms in the second photovoltaic layer to form the second photovoltaic layer having the second energy gap.

According to the above descriptions, in the thin-film solar cell of the present invention, by increasing the crystallization ratios of some of the microcrystalline semiconductor materials to change the energy gaps of the photovoltaic layers, the thin-film solar cell can present a favorable light absorption rate in the long-wavelength band. This can increase the utilization factor of light in the long-wavelength band to improve the overall photo-electric conversion efficiency of the thin-film solar cell. Moreover, the thin-film solar cell of the present invention may further be provided with a light reflective layer, which may have a rugged surface, to reflect light rays unabsorbed by the photovoltaic layer back into the photovoltaic layers. This provides additional light paths for the light rays to pass through the photovoltaic layers and result in a higher possibility for the light rays to be absorbed by the photovoltaic layers, thus further improving the overall photo-electric conversion efficiency of the thin-film solar cell. Furthermore, the present invention also provides a method for manufacturing a thin-film solar cell, by which the aforesaid thin-film solar cell can be manufactured.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic view of a thin-film solar cell according to an embodiment of the present invention;

FIG. 2 is a schematic view of a thin-film solar cell according to another embodiment of the present invention;

FIG. 3 is a schematic view of a thin-film solar cell according to a further embodiment of the present invention;

FIGS. 4A through 4F illustrate a flowchart of a process for manufacturing a thin-film solar cell according to an embodiment of the present invention; and

FIG. 5 illustrates a flowchart of a process for manufacturing a thin-film solar cell according to another embodiment of the present invention.

### DESCRIPTION OF THE PREFERRED EMBODIMENT

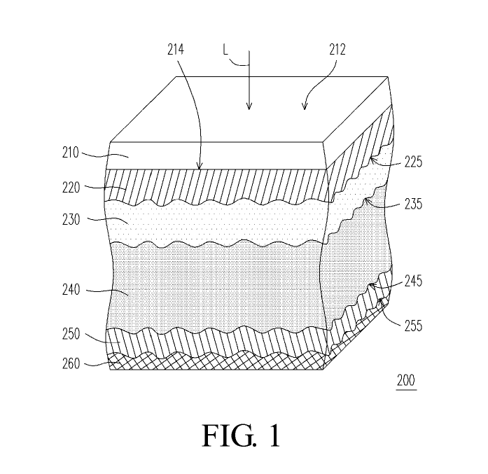

FIG. 1 is a schematic view of a thin-film solar cell according to an embodiment of the present invention. Referring to FIG. 1, the thin-film solar cell 200 comprises a light transmissive substrate 210, a transparent electrode 220, a first photovoltaic layer 230, a second photovoltaic layer 240 and a back electrode 250.

The light transmissive substrate 210 has a light incident surface 212 and a back surface 214 opposite to the light incident surface 212. The light transmissive substrate 210 is illustrated as a glass substrate in this embodiment; however, the present invention is not limited thereto. In other embodiments, the light transmissive substrate 210 may also be some other substrate with favorable light transmissivity, for example, a plastic substrate or a flexible substrate.

The transparent electrode 220 is disposed on the back surface 214, as shown in FIG. 1. In this embodiment, the transparent electrode 220 may be made of a transparent conductive material such as indium tin oxide (ITO), indium zinc oxide (IZO), indium tin zinc oxide (ITZO), zinc oxide, aluminum tin oxide (ATO), aluminum zinc oxide (AZO), cadmium indium oxide (CIO), cadmium zinc oxide (CZO), gallium zinc oxide (GZO) or fluorine tin oxide (FTO) or combinations thereof. Generally, as being disposed at the light incident side, the transparent electrode 220 may be called a front electrode.

The first photovoltaic layer 230 is disposed on the transparent electrode 220, as shown in FIG. 1. The first photovoltaic layer 230 is made of an amorphous semiconductor material, and has a first energy gap. In this embodiment, if the first photovoltaic layer 230 is made of an amorphous silicon (α-Si) thin film, then the first energy gap of the first photovoltaic layer 230 approximately ranges between 1.7 electron voltage and 1.8 electron voltage; thus, the light wavelength range absorbable by the first photovoltaic layer 230 will fall within the short-wavelength portions of the sunlight spectrum, e.g., the visible light band. However, this is only illustrated as an example; and in other embodiments, the first photovoltaic layer 230 may also be made of an amorphous silicon germanium (α-SiGe) thin film, an amorphous silicon carbide (α-SiC) thin film or some other amorphous semiconductor material, wherein different materials correspond to different energy gaps and the light bands absorbable by the first photovoltaic layer 230 also varies correspondingly. Additionally, in the embodiment depicted in FIG. 1, the surface 225 where the first photovoltaic layer 230 makes contact with the transparent electrode 220 may be designed to be irregularly rugged. In this way, when the light rays L enter the thin-film solar cell 200 from the light incident surface 212, the chance for the light rays L to be reflected away from the thin-film solar cell 200 by the surface 225 can be decreased; i.e., it is more likely for the light rays L to propagate into the thin-film solar cell 200.

The second photovoltaic layer 240 is disposed on the first photovoltaic layer 230 as shown in FIG. 1, and has a second energy gap lower than the first energy gap. The second photovoltaic layer 240 is made of a microcrystalline semiconductor material, and a crystallization ratio of the second photovoltaic layer 240 is between 30% and 100%. In this embodiment, the second energy gap of the second photovoltaic layer 240 ranges between 1.1 electron volt and 1.7 electron volt, for example.

Specifically, the second photovoltaic layer 240 is made of a microcrystalline silicon thin film (μc-Si) thin film, and may have an average grain size of between 50 nm and 500 nm. Thus, the second energy gap of the second photovoltaic layer 240 of this embodiment approximately ranges between 1.1 electron volt and 1.5 electron volt, which allows the second photovoltaic layer 240 to absorb light rays within a wavelength range of about 800 nm to 1100 nm (e.g., the red light, the near IR light and the far IR light). However, this is only illustrated as an example; and in some embodiments, the second photovoltaic layer 240 may also be made of a microcrystalline silicon germanium (μc-SiGe) thin film, a microcrystalline silicon carbide (μc-SiC) thin film or some other microcrystalline semiconductor material. In other embodiments, as germanium has an energy gap of about 0.6 electron volt, the second photovoltaic layer 240 may also be formed by doping germanium in the silicon thin film to reduce the energy gap of the original silicon thin film to be lower than the first energy gap. As compared with conventional thin-film solar cells that are unable to efficiently absorb long-wavelength light rays, the second photovoltaic layer 240 of this embodiment with an appropriate crystallization ratio and an appropriate energy gap can better absorb long-wavelength light rays to result in an improved utilization factor of light rays in the thin-film solar cell 200.

Similarly, in the embodiment depicted in FIG. 1, the surface 235 where the second photovoltaic layer 240 makes contact with the first photovoltaic layer 230 may be designed, for example, to be irregularly rugged in order to decrease the chance that the incident light rays L are reflected by the surface 235 so that the light rays L propagate into the second photovoltaic layer 240 more easily.

The back electrode 250 is disposed on the second photovoltaic layer 240, as shown in FIG. 1. In this embodiment, the back electrode 250 is made of, for example, a transparent conductive material, which may be one of the materials described above with respect to the transparent electrode 220 and thus will not be further described herein. The transparent conductive material of the back electrode 250 may be either identical to or different from that of the transparent electrode 220. In the embodiment depicted in FIG. 1, the surface 245 where the back electrode 250 makes contact with the second photovoltaic layer 240 may be designed, for example, to be irregularly rugged in order to decrease the chance that the incident light rays L are reflected by the surface 235 so that the light rays L propagate to the back electrode 250 more easily.

In this embodiment, the thin-film solar cell 200 further comprises a light reflective layer 260 disposed on the back electrode 250. The surface 255 where the light reflective layer 260 makes contact with the back electrode 250 may be designed, for example, to be irregularly rugged so that the light rays L become scattered to form more light paths. The light reflective layer 260 may be made of one or more materials selected from a group consisting of a white paint, a metal, a metal oxide, an organic material and combinations thereof. However, it shall be noted that, if the light reflective layer 260 is made of a conductive material such as a metal, then a light transmissive insulation layer (not shown) may be disposed between the light reflective layer 260 and the back electrode 250 to avoid short-circuit between the light reflective layer 260 and the back electrode 250.

In other words, the light rays L entering the thin-film solar cell 200 from the light incident surface 212 pass sequentially through the light transmissive substrate 210, the transparent electrode 220, the first photovoltaic layer 230, the second photovoltaic layer 240 and the back electrode 250 and then propagates to the light reflective layer 260, wherein the second photovoltaic layer 240 is adapted to absorb long-wavelength light rays. Besides, light rays L that are not absorbed by the first photovoltaic layer 230 and the second photovoltaic layer 240 pass through the back electrode 250 and are then reflected by the light reflective layer 260 back into the photovoltaic layers 230, 240 to be recycled. Here, light rays L that can be reflected by the light reflective layer 260 have a wavelength substantially ranging between 600 nm and 1100 nm.

As can be known from above, the thin-film solar cell 200 of this embodiment is, for example, a tandem thin-film solar cell formed of the first photovoltaic layer 230 and the second photovoltaic layer 240, in which the second photovoltaic layer 240 with an appropriate crystallization ratio and an appropriate energy gap is adapted to absorb long-wavelength light rays. Moreover, because the thin-film solar cell 200 is further provided with the light reflective layer 260 to reflect light rays L that are unabsorbed by the photovoltaic layers 230, 240, the thin-film solar cell 200 can utilize various bands of the light rays L efficiently for photo-electric conversion, thus improving the overall photo-electric conversion efficiency of the thin-film solar cell 200.

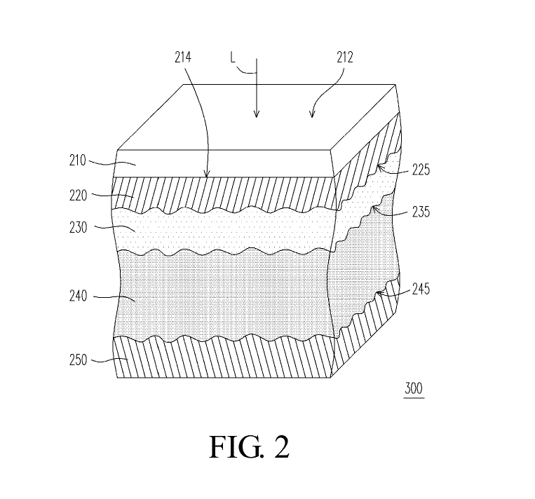

FIG. 2 is a schematic view of a thin-film solar cell according to another embodiment of the present invention. Referring to FIG. 2, the thin-film solar cell 300 comprises most of the components of the thin-film solar cell 200. For these identical components, they will still be denoted with the same reference numerals and will not be further described hereinbelow.

In the thin-film solar cell 300, the back electrode 250 may also be made of a reflective and electrically conductive material to have advantages of both the back electrode 250 and the light reflective layer 260 of the thin-film solar cell 200. In an embodiment, the reflective and conductive material of the back electrode 250 may also reflect light rays with a long wavelength substantially between 600 nm and 1100 nm. In other words, the thin-film solar cell 300 may also not be provided with the light reflective layer 260 while still achieving the efficacy of the thin-film solar cell 200.

The thin-film solar cells 200, 300 of the aforesaid embodiments are of a tandem thin-film solar cell structure, although the present invention is not limited thereto. This will be described hereinbelow.

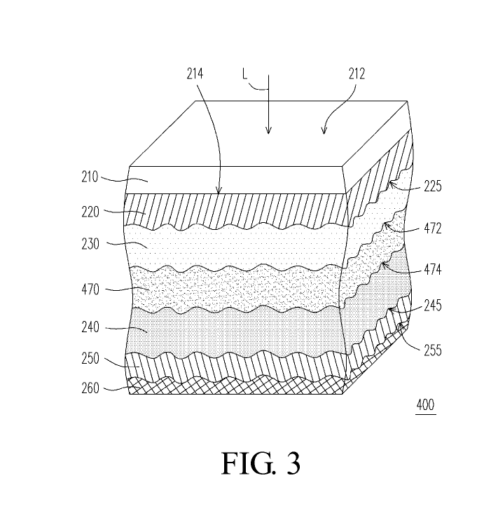

FIG. 3 is a schematic view of a thin-film solar cell according to a further embodiment of the present invention. Referring to FIG. 3, the thin-film solar cell 400 comprises most of the components of the thin-film solar cell 200. For these identical components, they will still be denoted with the same reference numerals and will not be further described hereinbelow.

The thin-film solar cell 400 differs from the thin-film solar cell 200 mainly in that, the thin-film solar cell 400 further comprises a third photovoltaic layer 470 disposed between the first photovoltaic layer 230 and the second photovoltaic layer 240. In other words, the thin-film solar cell 400 is of a triple thin-film solar cell structure. Particularly, the third photovoltaic layer 470 has a third energy gap, which is higher than the second energy gap but lower than the third energy gap.

In the thin-film solar cell 400, the third photovoltaic layer 470 is made of at least one of an amorphous semiconductor material and a microcrystalline semiconductor material. The material of the third photovoltaic layer 470 may be either the same as or different from that of the first photovoltaic layer 230 or the second photovoltaic layer 240. Briefly speaking, a third energy gap of the third photovoltaic layer 470 may be made to be between the first energy gap of the first photovoltaic layer 230 and the second energy gap of the second photovoltaic layer 240 by, for example, appropriately choosing the material, designing the crystallization ratio or adjusting the dopant concentration.

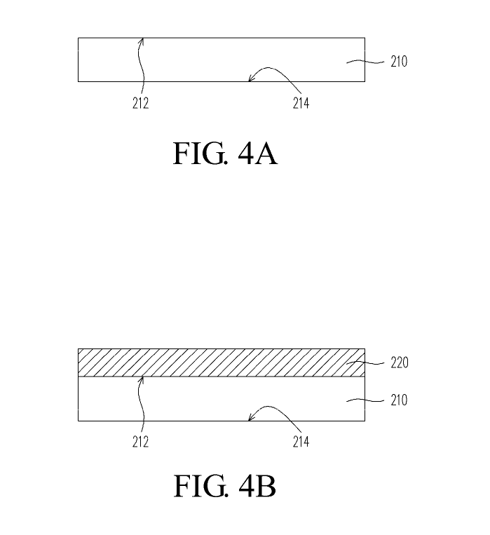

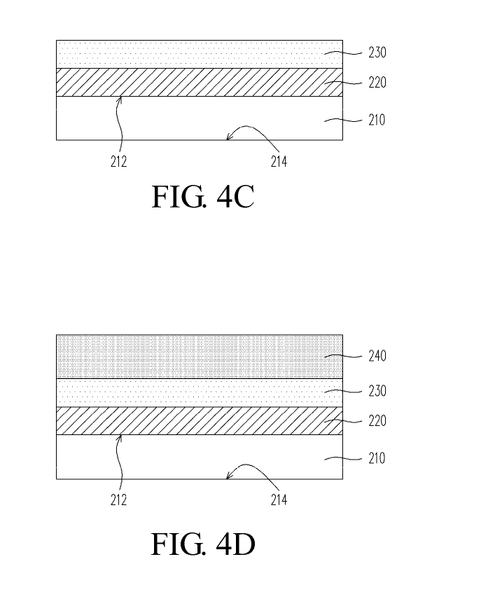

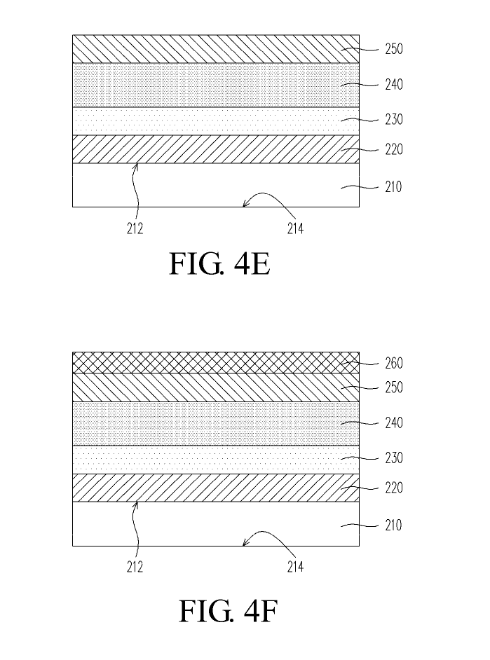

For example, in the thin-film solar cell 400 depicted in FIG. 4, the first photovoltaic layer 230 has a first energy gap of 1.7 electron volt, the third photovoltaic layer 470 has a third energy gap of 1.5 electron volt, and the second photovoltaic layer 240 has a second energy gap of 1.3 electron volt. Then, the thin-film solar cell 400 will be able to absorb light rays ranging from the short wavelength bands to the long wavelength bands, thereby resulting in improved photo-electric conversion efficiency.

Furthermore, in the thin-film solar cell 400, the surface 472 where the first photovoltaic layer 230 makes contact with the third photovoltaic layer 470 or the surface 474 where the second photovoltaic layer 240 makes contact with the third photovoltaic layer 470 may be designed to be, for example, irregularly rugged so that the light rays L propagates into the thin-film solar cell 400 more easily.

Because the thin-film solar cell 400 is provided with the second photovoltaic layer 240, the thin-film solar cell 400 also has improved photo-electric conversion efficiency.

Hereinafter, a method for manufacturing the thin-film solar cell 200 will be described.

FIGS. 4A through 4F illustrate a flowchart of a process for manufacturing a thin-film solar cell according to an embodiment of the present invention. It shall be noted that, the method for manufacturing the thin-film solar cell 200 is described herein in a context of forming individual layers from bottom to top. Firstly, a light transmissive substrate 210, which has a light incident surface 212 and a back surface 214 opposite to the light incident surface 212, is provided. In this embodiment, the light transmissive substrate 210 is, for example, a glass substrate.

Then as shown in FIG. 4B, a transparent electrode 220 is formed on the back surface 214. In this embodiment, the transparent electrode 220 may be made of one of the materials set forth above with respect to the transparent conductive layer and is formed through, for example, a sputtering process, a metal organic chemical vapor deposition (MOCVD) process or an evaporation process.

Next, referring to FIG. 4C, a first photovoltaic layer 230 is formed on the transparent electrode 220. The first photovoltaic layer 230 is made of an amorphous semiconductor material and has a first energy gap. In this embodiment, the first photovoltaic layer 230 may be formed through, for example, a radio frequency plasma enhanced chemical vapor deposition (RF PECVD) process, a very high frequency plasma enhanced chemical vapor deposition (VHF PECVD) process or a microwave plasma enhanced chemical vapor deposition (MW PECVD) process.

Afterwards, as shown in FIG. 4D, a second photovoltaic layer 240 is formed on the first photovoltaic layer 230. The second photovoltaic layer 240 has a second energy gap lower than that of the first energy gap. The second photovoltaic layer 240 is made of a microcrystalline semiconductor material, and has a crystallization ratio of between 30% and 100%. In this embodiment, the second photovoltaic layer 240 may be formed through, for example, an RF PECVD process, a VHF PECVD process or an MW PECVD process. For instance, in an embodiment, the second photovoltaic layer 240 is formed through a VHF PECVD process. In this case, the plasma frequency, deposition pressure and ratio of hydrogen, SiH₄ or other process gases may be appropriately adjusted to fabricate a microcrystalline silicon layer with a desired crystallization ratio.

It shall be appreciated that, during the process of forming the second photovoltaic layer 240, an annealing process may be further performed on the second photovoltaic layer 240 so that the second photovoltaic layer 240 has a crystallization ratio of between 30% and 100% or has an average grain size of between 50 nm and 500 nm. This imparts the second photovoltaic layer 240 with a second energy gap. More particularly, in an embodiment, the annealing process may be performed on the second photovoltaic layer 240 by, for example, a laser annealing apparatus (not shown) to impart the second photovoltaic layer 240 with a specific crystallization ratio or a specific average grain size. However, the present invention has no limitation on the manner in which the annealing process is performed. In some embodiments, it is also possible that the second photovoltaic layer 240 is firstly formed through one of the aforesaid deposition processes and then an appropriate annealing process is performed on the second photovoltaic layer 240 to impart the second photovoltaic layer 240 with a desired average grain size.

Furthermore, in some embodiments, subsequent to the step of forming the second photovoltaic layer 240, a doping process, for example, may be performed on the second photovoltaic layer 240 so that the second energy gap ranges between 1.1 electron volt and 1.7 electron volt. For instance, germanium atoms may be doped in the second photovoltaic layer 240 to form the second photovoltaic layer 240 with the second energy gap. The doping process may be performed by a furnace, an ion implanter or other appropriate doping equipment, or performed in any other known ways of doping, and the present invention is not limited thereto.

Thereafter, as shown in FIG. 4E, a back electrode 250 is formed on the second photovoltaic layer 240. In this embodiment, the back electrode 250 is formed through, for example, a sputtering process, a MOCVD process or an evaporation process, but the present invention is not limited thereto.

Next, as shown in FIG. 4F, if the back electrode 250 is made of a transparent conductive material, this embodiment further comprises forming a light reflective layer 260 on the back electrode 250. The light reflective layer 260 at least reflects a light ray (not shown) with a wavelength substantially between 600 nm and 1100 nm. Furthermore, if the light reflective layer 260 is made of a conductor material, this embodiment further comprises forming a light transmissive insulation layer (not shown) between the light reflective layer 260 and the back electrode 250 so as to avoid occurrence of short-circuit between the light reflective layer 260 and the back electrode 250.

It shall be appreciated that, in the steps shown in FIG. 4A through FIG. 4F, surfaces where the individual layers (i.e., the transparent electrode 220, the first photovoltaic layer 230, the second photovoltaic layer 240 and the back electrode 250) make contact with each other may be made to be irregularly rugged through etching or in other appropriate ways to form layered structure of the thin-film solar cell 200 shown in FIG. 1. Of course, the present invention is not limited to formation of irregularly rugged surfaces between all the layers, and in some embodiments, only between some of the layers are formed such irregularly rugged surfaces.

Thus, through the aforesaid steps shown in FIG. 4A through FIG. 4F, the manufacturing process of the thin-film solar cell 200 is completed.

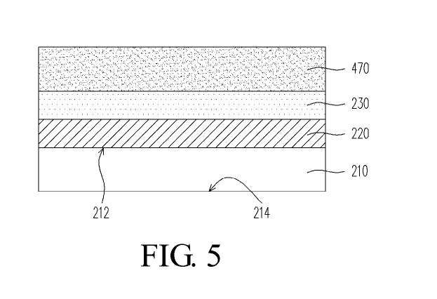

On the other hand, the manufacturing process of the thin-film solar cell 400 is similar to that of the thin-film solar cell 200. Briefly speaking, as shown in FIG. 5, after the step of forming the first photovoltaic layer 230 (FIG. 4C) but before the step of forming the second photovoltaic layer 240 (FIG. 4D), a third photovoltaic layer 470 having a third energy gap may be formed on the first photovoltaic layer 230, wherein the third energy gap is between the first energy gap and the second energy gap. Then, the steps of FIG. 4D through FIG. 4F are carried out to complete the manufacturing process of the thin-film solar cell 400.

In the step shown in FIG. 5, the manufacturing method of the thin-film solar cell 400 further comprises performing an annealing process on the third photovoltaic layer 470 to crystallize the third photovoltaic layer 470. Here, a laser annealing apparatus (not shown) may be used to perform the annealing process on the third photovoltaic layer 470, but the present invention is not limited thereto.

The way in which the annealing process is performed on the third photovoltaic layer 470 may be either the same as or different from the way in which the annealing process is performed on the second photovoltaic layer 240. Because the second photovoltaic layer 240 and the third photovoltaic layer 470 may be made of different materials or have different crystallization ratios from each other, the annealing processes or process parameters of the annealing processes used for the second photovoltaic layer 240 and the third photovoltaic layer 470 may be different from each other depending on practical requirements. Similarly, irregularly rugged surfaces may also be formed between all or only some of the individual layers of the thin-film solar cell 400 through etching or in other appropriate ways.

According to the above descriptions, the thin-film solar cell of the present invention has the following advantages. First of all, by increasing the crystallization ratio of the microcrystalline semiconductor in some of the photovoltaic layers to change the energy gap thereof, the thin-film solar cell can be made to absorb light rays in long-wavelength bands. Therefore, as compared to conventional thin-film solar cells, the thin-film solar cell of the present invention can absorb light rays in long-wavelength bands more efficiently to result in improved photo-electric conversion efficiency. Moreover, the thin-film solar cell of the present invention may further be provided with a light reflective layer which is adapted to reflect light rays of in long-wavelength bands. In this way, light rays unabsorbed by the photovoltaic layers can be reflected by the light reflective layer back into the photovoltaic layers so that the light rays can be re-absorbed by the photovoltaic layers to improve the efficiency of the photovoltaic layers absorbing light rays. This further improves the photo-electric conversion efficiency of the thin-film solar cell of the present invention. Furthermore, the present invention also provides a method for manufacturing a thin-film solar cell, by which the aforesaid thin-film solar cell can be manufactured.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A thin-film solar cell, comprising:
a light transmissive substrate, having a light incident surface and a back surface opposite to the light incident surface;
a transparent electrode disposed on the back surface;
a first photovoltaic layer disposed on the transparent electrode, the first photovoltaic layer being made of an amorphous semiconductor material and having a first energy gap;
a second photovoltaic layer disposed on the first photovoltaic layer, the second photovoltaic layer having a second energy gap lower than the first energy gap, the second photovoltaic layer being made of a microcrystalline semiconductor material with a crystallization ratio of between 30% and 100%, and the second photovoltaic layer being adapted to absorb light rays with a wavelength of between 600 nm and 1100 nm; and
a back electrode disposed on the second photovoltaic layer.

2. The thin-film solar cell as claimed in claim 1, wherein the second photovoltaic layer has an average grain size of between 50 nm and 500 nm.

3. The thin-film solar cell as claimed in claim 1, wherein the second energy gap ranges between 1.1 electron volt and 1.7 electron volt.

4. The thin-film solar cell as claimed in claim 1, further comprising a third photovoltaic layer disposed between the first photovoltaic layer and the second photovoltaic layer, wherein the third photovoltaic layer has a third energy gap higher than the second energy gap but lower than the first energy gap.

5. The thin-film solar cell as claimed in claim 4, wherein the third photovoltaic layer is made of at least one of an amorphous semiconductor material and a microcrystalline semiconductor material.

6. The thin-film solar cell as claimed in claim 1, wherein the back electrode is made of a transparent conductive material or a reflective conductive material.

7. The thin-film solar cell as claimed in claim 1, wherein when the back electrode is made of the transparent conductive material, the thin-film solar cell further comprises a light reflective layer disposed on the back electrode.

8. The thin-film solar cell as claimed in claim 7, wherein a light ray entering the thin-film solar cell via the light incident surface passes sequentially through the light transmissive substrate, the transparent electrode, the first photovoltaic layer, the second photovoltaic layer and the back electrode to the light reflective layer, and the light reflective layer at least reflects the light ray with a wavelength of substantially between 600 nm and 1100 nm.

9. The thin-film solar cell as claimed in claim 7, wherein the light reflective layer is made of one or more materials selected from a group consisting of a white paint, a metal, a metal oxide, an organic material and combinations thereof.

10. The thin-film solar cell as claimed in claim 1, wherein the second photovoltaic layer is made of germanium (Ge).

11. A method for manufacturing a thin-film solar cell, comprising:
providing a light transmissive substrate having a light incident surface and a back surface opposite to the light incident surface;
forming a transparent electrode on the back surface;
forming a first photovoltaic layer on the transparent electrode, the first photovoltaic layer being made of an amorphous semiconductor material and having a first energy gap;
forming a second photovoltaic layer on the first photovoltaic layer, the second photovoltaic layer having a second energy gap lower than the first energy gap, the second photovoltaic layer being made of a microcrystalline semiconductor material with a crystallization ratio of between 30% and 100%, and the second photovoltaic layer being adapted to absorb a light ray with a wavelength of between 600 nm and 1100 nm; and
forming a back electrode on the second photovoltaic layer.

12. The method for manufacturing a thin-film solar cell as claimed in claim 11, further comprising performing an annealing process on the second photovoltaic layer so that the second photovoltaic layer has a crystallization ratio of between 30% and 100%.

13. The method for manufacturing a thin-film solar cell as claimed in claim 11, further comprising performing an annealing process on the second photovoltaic layer so that the second photovoltaic layer has an average grain size of between 50 nm and 500 nm.

14. The method for manufacturing a thin-film solar cell as claimed in claim 11, further comprising performing a doping process on the second photovoltaic layer so that the second energy gap ranges between 1.1 electron volt and 1.7 electron volt.

15. The method for manufacturing a thin-film solar cell as claimed in claim 11, wherein, after the step of forming the first photovoltaic layer but before the step of forming the second photovoltaic layer, the method further comprises:
forming a third photovoltaic layer having a third energy gap on the first photovoltaic layer, wherein the third energy gap is between the first energy gap and the second energy gap.

16. The method for manufacturing a thin-film solar cell as claimed in claim 15, further comprising performing an annealing process on the third photovoltaic layer to crystallize the third photovoltaic layer.

17. The method for manufacturing a thin-film solar cell as claimed in claim 11, wherein when the back electrode is made of a transparent conductive material, the method further comprises:
forming a light reflective layer on the back electrode, wherein the light reflective layer at least reflects a light ray having a wavelength of substantially between 600 nm and 1100 nm.

18. The method for manufacturing a thin-film solar cell as claimed in claim 17, wherein the light reflective layer is made of one or more materials selected from a group consisting of a white paint, a metal, a metal oxide, an organic material and combinations thereof.

19. The method for manufacturing a thin-film solar cell as claimed in claim 18, wherein when the light reflective layer is made of a conductor material, the method further comprises:
forming a light transmissive insulation layer between the light reflective layer and the back electrode.

20. The method for manufacturing a thin-film solar cell as claimed in claim 11, further comprising doping Ge atoms in the second photovoltaic layer to form the second photovoltaic layer having the second energy gap.
